(19) United States
(12) Patent Application Publication
(10) Pub. No.: US 2011/0157446 A1
(43) Pub. Date: Jun. 30, 2011

(54) IMAGE SENSOR AND METHOD OF MANUFACTURING THE SAME, AND SENSOR DEVICE

(75) Inventors: Hiroto Kasai, Tokyo (JP); Tatsuya Minakawa, Kanagawa (JP); Yuichi Aki, Tokyo (JP); Makoto Hashimoto, Kanagawa (JP); Ayumu Taguchi, Tokyo (JP); Takeshi Yamasaki, Kanagawa (JP); Isao Ichimura, Tokyo (JP); Keiichi Maeda, Kanagawa (JP)

(73) Assignee: SONY CORPORATION, Tokyo (JP)

(21) Appl. No.: 12/970,065

(22) Filed: Dec. 16, 2010

(30) Foreign Application Priority Data
Dec. 28, 2009 (JP) P2009-298487

(51) Int. Cl. H04N 5/335; H01L 31/18

(52) U.S. Cl. 348/308; 438/69; 257/E31.127

(57) ABSTRACT

An image sensor is provided. The image sensor includes a photoelectric conversion portion including a light receiving element; and a well region defined by a wall structure that is formed integrally on the photoelectric conversion portion, wherein the well region is positioned to correspond to the light receiving element of the photoelectric conversion portion. An image sensor device and methods of manufacture are also provided.

### CROSS REFERENCES TO RELATED APPLICATIONS

The present application claims priority to Japanese Priority Patent Application JP 2009-298487 filed in the Japan Patent Office on Dec. 28, 2009, the entire content of which is hereby incorporated by reference.

### BACKGROUND

The present application relates to an image sensor using a solid-state image pickup element and a method of manufacturing the same, and a sensor device having the same mounted thereto. More particularly, the present application relates to a structure of an image sensor for carrying out a measurement for either a gel-like or liquid specimen and a method of manufacturing the same, and a sensor device having the same mounted thereto.

In recent years, a demand for either a chemical sensor or a biosensor for displaying a result of a pH measurement about a liquid solution, a result of an analysis about DNA or proteins, or the like in the form of a two-dimensional image has increased. A Light Addressable Potentiometric Sensor (LAPS) utilizing a Surface Potential Measuring Method (SPV Method) of reading a surface potential of a semiconductor element from a photoexcited current caused by a condensed light spot, for example, is known as such a chemical sensor. The LAPS, for example, is described in Japanese Patent Laid-Open Nos. 2002-131276 and 2008-241335 (hereinafter referred to as Patent Documents 1 and 2).

On the other hand, although each of the existing chemical sensors, for example, described in Patent Documents 1 and 2 can take in a detected image in the form of a two-dimensional map, a transparent substrate and a transparent electrode are both required because a light is made incident to a substrate surface. In addition, each of those chemical sensors includes one light source and one element. Therefore, even when the light source is made in a spot state, photoexcited carriers generated diffuse in a planar direction of a semiconductor element, so that a range of the photoexcited current becoming an object of an observation spreads. For this reason, there is caused such a problem that an image resolution is low.

Then, heretofore, the chemical sensor or the biosensor using a solid-state image pickup element such as a Charge Coupled Device (CCD) or a Complementary Metal Oxide Semiconductor (CMOS) image sensor as a detecting section has been proposed as a device which has a high detection sensitivity, from which a signal containing therein a less noise component can be obtained, and which can output a charge signal as two-dimensional data. The chemical sensor or the biosensor, for example, is described in Japanese Patent Laid-Open Nos. 2004-301648, 2009-165219, 2006-162585, and 2005-227155 (hereinafter referred to as Patent Documents 3 to 6). In addition, a liquid solution component sensor has also been known in which a light source, cells and a light receiving portion are formed integrally with one another on a semiconductor substrate. This liquid solution component sensor, for example, is described in Japanese Patent Laid-Open No. Hei 6-18421 (hereinafter referred to as Patent Document 7).

### SUMMARY

However, the related art described above involves the following problems. That is to say, in the case of the analyzing apparatuses described in Patent Documents 3 and 4, when the high resolution is required, a section for carrying out alignment between a well and a detector needs to be specially provided. As a result, there is caused such a problem that the manufacturing equipment for the analyzing apparatus is difficult to miniaturize and simplify.

On the other hand, in the case of the sensor described in Patent Document 5, since a specimen is made to directly contact a conductive thin film and an electric signal generated based on a chemical reaction caused in the specimen is detected by a diode, the small electric signal needs to be caught by the conductive thin film. For this reason, for example, when the conductive thin film is made of a metal, there is encountered such a problem that surface roughness, an oxidation state and the like exert a large influence on the detection sensitivity, and thus the maintenance and management for a surface shape and a formation process of the conductive thin film need to be very severely carried out. In addition, in the case of the sensor described in Patent Document 5, the CCD merely senses the electric signal generated from the specimen, and thus cannot output the optimal phenomenon in the form of a two-dimensional image.

In addition, the image sensor described in Patent Document 6 observes the specimen, as an object of a movement, which is directly placed on a protective film of the image sensor. Therefore, there is caused such a problem that that image sensor is unsuitable for a measurement of a specimen having a low viscosity, and a plurality kind of specimens cannot be measured at the same time. Moreover, the sensor described in Patent Document 7 is manufactured by sticking a plurality of substrates to one another. At that time, however, there is caused such a problem that it is difficult to precisely carry out the alignment for a plurality of substrates. Furthermore, the sensor described in Patent Document 7 is manufactured for the purpose of analyzing components of a specimen such as a concentration, and thus cannot output the optical phenomenon caused in the specimen in the form of the two-directional image similarly to the case of the sensor described in Patent Document 5.

The present application has been made in order to solve the problems described above, and it is therefore desirable to provide an image sensor with which manufacturing equipment for the image sensor can be miniaturized and simplified, and thus which can be manufactured at a low cost and a method of manufacturing the same, and a sensor device having the same mounted thereto.

In order to attain the desire described above, according to an embodiment, there is provided an image sensor including: a photoelectric conversion portion including a plurality of light receiving elements for converting an incident light into an electric signal; an insulating layer made of a light transmissive material and formed so as to cover said photoelectric conversion portion; and one or multiple wells formed above the insulating layer overlying said photoelectric conversion portion. An optical phenomenon caused in a specimen filled within the one or multiple wells is detected by the plurality of light receiving elements of the photoelectric conversion portion.

In an embodiment, an image sensor is provided. The image sensor including a photoelectric conversion portion including a light receiving element; and a well region defined by a wall structure that is formed integrally on the photoelectric conversion portion, wherein the well region is positioned to correspond to the light receiving element of the photoelectric conversion portion.

In an embodiment, the well region is configured as any one of a quadrangular shape and a hexagonal shape.

In an embodiment, the wall structure includes a material selected from the group consisting of Au, Ag, Cu, Ni, Cr, Pt, Pd, Zn, Cd, and an alloy thereof.

In an embodiment, a side surface of the well region includes a side surface material that does not transmit light.

In an embodiment, the well region is configured to receive a biological specimen.

In an embodiment, the light receiving element is configured to detect the light from the biological specimen.

In an embodiment, the well region is covered with a protective film configured to protect the well region from reaction with the biological specimen.

In an embodiment, the photoelectric conversion portion is a charge coupled device or a complementary metal oxide semiconductor.

In an embodiment, an insulating layer is formed between the photoelectric conversion portion and the well region.

In an embodiment, a light reflective layer is formed on the wall structure.

In an embodiment, a light absorptive layer is formed on the wall structure.

In an embodiment, the well region and the light receiving element are substantially same in size.

In an embodiment, the well region is configured to be positioned over the light receiving element.

In an embodiment, an image sensor device is provided. The image sensor device including an image sensor including a photoelectric conversion portion and a well region, wherein the photoelectric conversion portion includes a light receiving element, wherein the well region is defined by a wall structure that is formed integrally on the photoelectric conversion portion, and wherein the well region is positioned to correspond to the light receiving element of the photoelectric conversion portion.

In an embodiment, a method of manufacturing an image sensor is provided. The method including forming a photoelectric conversion portion including a light receiving element; and forming a well region defined by a wall structure that is formed integrally on the photoelectric conversion portion, wherein the well region is positioned to correspond to the light receiving element of the photoelectric conversion portion.

In an embodiment, the well region is configured as any one of a quadrangular shape and a hexagonal shape.

In an embodiment, the wall structure includes a metal material selected from the group consisting of Au, Ag, Cu, Ni, Cr, Pt, Pd, Zn, Cd, and an alloy thereof.

In an embodiment, the metal material of the wall structure is formed by electroforming.

In an embodiment, the wall structure is formed by combining a hard mask layer composed of the metal material and a resist layer.

In an embodiment, the light receiving element is configured to detect the light from the biological specimen.

In an embodiment, the well region is configured to receive a biological specimen.

In an embodiment, the well region is covered with a protective film configured to protect the well region from reaction with the biological specimen.

In an embodiment, the photoelectric conversion portion is a charge coupled device or a complementary metal oxide semiconductor.

In an embodiment, an insulating layer is formed between the photoelectric conversion portion and the well region.

In an embodiment, a light reflective layer is formed on the wall structure.

In an embodiment, a light absorptive layer is formed on the wall structure.

In an embodiment, the well region and the light receiving element are substantially same in size.

In an embodiment, the well region is configured to be positioned over the light receiving element.

In an embodiment, a method of manufacturing an image sensor device is provided. The method including forming a photoelectric conversion portion of the image sensor, the photoelectric conversion portion including a light receiving element; and forming a well region of the image sensor, the well region being defined by a wall structure that is formed integrally on the photoelectric conversion portion, wherein the well region is positioned to correspond to the light receiving element of the photoelectric conversion portion.

According to the present application, since the photoelectric conversion portion(s) and the one or multiple wells are formed integrally with each other, the manufacturing equipment for the image sensor or the sensor device can be miniaturized and simplified, and also the image sensor or the sensor device can be manufactured at the low cost.

Additional features and advantages are described herein, and will be apparent from the following Detailed Description and the figures.

### BRIEF DESCRIPTION OF THE FIGURES

FIG. 1 is a cross sectional view schematically showing a structure of an image sensor according to a first embodiment;

FIGS. 2A to 2C are respectively views showing a method of manufacturing the image sensor according to a second embodiment in the order of processes;

FIGS. 3A to 3F are respectively cross sectional views showing a method of forming a well by utilizing an electroforming method in the order of processes;

FIGS. 4A to 4G are respectively cross sectional views showing a method of forming a well in an image sensor according to a change of the second embodiment by using a wall structure including a hard mask layer in the order of processes; and

FIGS. 5A to 5C are respectively cross sectional views showing a method of forming a sensor device according to a third embodiment in the order of processes.

### DETAILED DESCRIPTION

Embodiments of the present application will be described in detail hereinafter with reference to the drawings.

1. First Embodiment (structure of image sensor)

2. Second Embodiment (manufacturing method: method of forming wells by utilizing electroforming method)

3. Change of Second Embodiment (manufacturing method: method of forming wells by using wall structure including hard mask layer)

4. Third Embodiment (sensor device)

### 1. First Embodiment

### Structure of Image Sensor

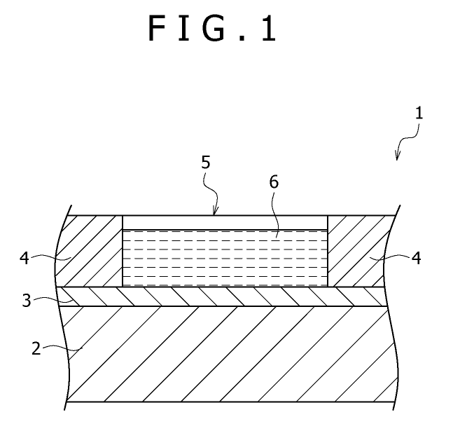

Firstly, an image sensor according to a first embodiment will be described with reference to FIG. 1. FIG. 1 is a cross sectional view schematically showing a structure of an image sensor according to a first embodiment. As shown in FIG. 1, in the image sensor 1 of the first embodiment, one or multiple wells 5 in which either a gel-like or liquid specimen 6 as an object of a measurement is accumulated are formed on a photoelectric conversion portion 2 through an insulating layer 3.

Photoelectric Conversion Portion 2

The photoelectric conversion portion 2 detects an optical phenomenon caused in the specimen 6 and outputs the optical phenomenon thus detected in the form of an electric signal. A plurality of light receiving elements are disposed in a matrix in the photoelectric conversion portion 2. Such a photoelectric conversion portion 2 can be composed of a solid-state image pickup element such as a Charge Coupled Device (CCD) or a Complementary Metal Oxide Semiconductor (CMOS).

Insulating Layer 3

The insulating layer 3 electrically insulates the photoelectric conversion portion 2 and a wall structure 4 composing the well 5 from each other, and is made of a material which exerts no influence on the light detection in the specimen 6 and each of the light receiving elements. Specifically, the insulating layer 3 can be made of an inorganic material such as a silicon oxide (SiO₂) or a silicon nitride (SiNO, having high permeability, or a polymer material, such as polyimide, having a high melting point and high permeability.

Well 5

The well 5 is a space zoned by the wall structure 4, and, for example, is provided every one or multiple pixels of the light receiving element provided in the photoelectric conversion portion 2. Also, an optical phenomenon caused in either the gel-like or liquid specimen 6 as an object of a measurement is measured within the well 5. A height, a width and a strength of the wall structure 4 composing the well 5 are especially by no means limited, and thus all it takes is that a predetermined amount of specimen 6 can be accumulated with the height, the width and the strength of the wall structure 4 composing the wall 5.

In addition, the well 5, for example, can have either a quadrangular shape or a hexagonal shape in terms of planar view. When the well 5 has the quadrangular shape in terms of planar view, the detection precision is enhanced because the well 5 can have the shape size which is either the same as that of the light receiving element of the photoelectric conversion portion 2 or the integral multiples of the shape size of the light receiving element of the photoelectric conversion portion 2. In particular, when the well 5 has the hexagonal shape in terms of planar view, since a light emitted within the well 5 becomes easy to multiply reflect, the light receiving element can take in a light emission phenomenon caused within the well 5 at a maximum. In addition, in the case where the specimen 6 contains therein beads, when the well 5 has the hexagonal shape in terms of planar view, the detection precision is enhanced because the beads become easy to undergo the close packing.

In addition, preferably, the wall structure 4 is made of a metallic material or a part of the wall structure 4 has a metallic layer. It is noted that when the part of the wall structure 4 has the metallic layer, a material composing other parts has to have such heat resistance as to withstand a mounting process. The wall structure 4 is made of such a material, whereby the light condensing effect for the light receiving element and the light receiving efficiency of the light receiving element can be enhanced.

In addition, preferably, at least a side surface of the well 5 (the wall structure 4) is made of a material not transmitting a light. As a result, the noises can be reduced, and thus the optical phenomenon caused in the specimen 6 can be detected with a high resolution. In addition, in the image sensor 1 of the first embodiment, a protective film may be formed on a surface of the wall structure 4. As a result, for example, it is possible to prevent an interaction between the specimen 6 and the well 5 (the wall structure 4), and a change of properties, and deterioration of the wall structure 4.

As described above, since in the image sensor 1 of the first embodiment, the photoelectric conversion element 2 and the well 5 are formed integrally with each other, the alignment work and section become unnecessary. In addition, since the well 5 can be formed in the wafer process similarly to the case of the photoelectric conversion element 2, the alignment precision can be suppressed within several micron meters. As a result, the analysis can be carried out with the high resolution.

Moreover, since in the image sensor 1 of the first embodiment, the pixels of the light receiving element, and wells 5 can also be formed so as to correspond to each other, the analysis can be realized with the high resolution. Furthermore, since culture or the like of a cell can be carried out within the well 5, a temporal change of the properties of the specimen 5 can also be observed.

### 2. Second Embodiment

### Outline of Method of Manufacturing Image Sensor

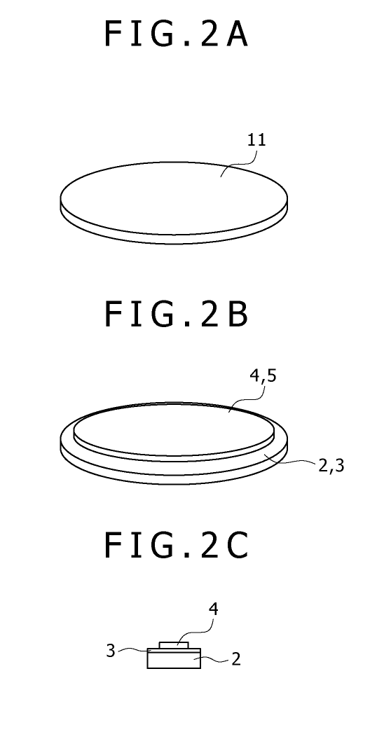

Next, a method of manufacturing the image sensor of the first embodiment described above will be described as a second embodiment with reference to FIGS. 2A to 2C. FIGS. 2A to 2C are respectively views showing a method of manufacturing the image sensor according to a second embodiment in the order of processes. In the second embodiment, firstly, as shown in FIG. 2A, the solid-state image pickup element such as the CCD or the CMOS is formed as the photoelectric conversion element 2 on a semiconductor wafer 11, and the insulating layer 3 is formed on the photoelectric conversion element 2. The methods of manufacturing the photoelectric conversion element 2 and the insulating layer 3 are by no means limited, and thus known methods can be applied thereto, respectively.

Next, as shown in FIG. 2B, the well 5 is formed on the insulating layer 3. Although a method of forming the well 5 is especially by no means limited, for example, when the wall structure 4 is made of a metallic material, an electroforming method or the like which will be described later can be applied to the method of forming the well 5. After that, as shown in FIG. 2C, the semiconductor wafer 11 is cut into the image sensor 1 by utilizing the known method.

Formation of Well 5 by Utilizing Electroforming Method

Next, a method of forming the well 5 at the wafer level by utilizing the electroforming method (metal plating method) will be concretely described by exemplifying the case where the photoelectric conversion element 2 is an existing CMOS. By utilizing the electroforming method, it is possible to form a thick metallic film, having a thickness of several micron meters to several tens of micron meters, for which it takes time to deposit a film by utilizing either a Chemical Vapor Deposition (CVD) method or a Physical Vapor Deposition (PVD) method, and thus which is difficult to form by utilizing either the CVD method or the PVD method. From this reason, the electroforming method is generally used for formation of bumps of a semiconductor device, formation of a structure of a Micro Electro Mechanical Systems (MEMS) device, or the like.

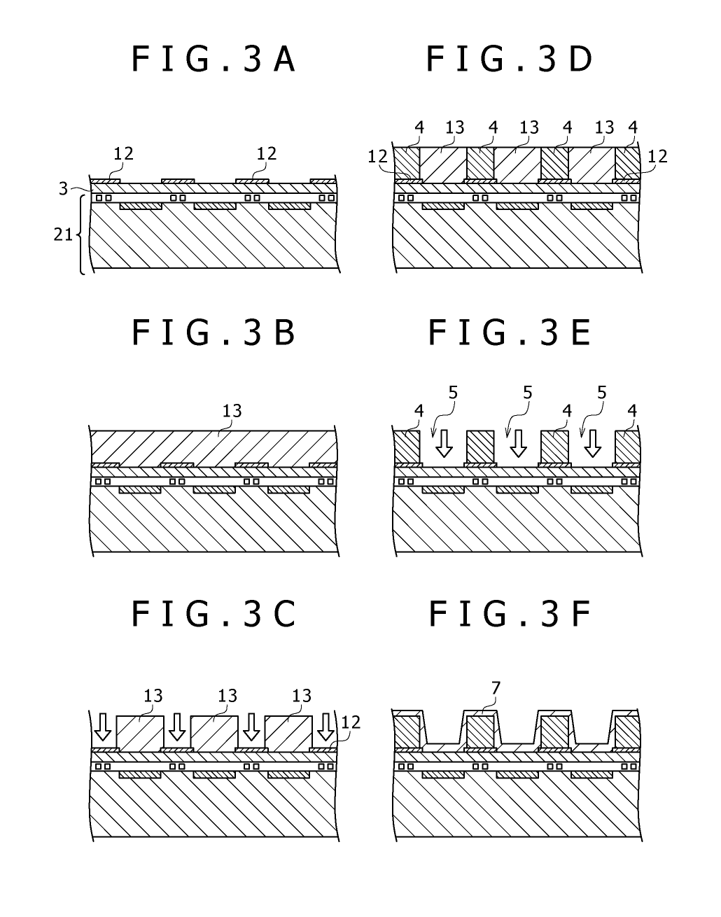

FIGS. 3A to 3F are respectively cross sectional views showing a method of forming a well 5 by utilizing the electroforming method in the order of processes. In the case where the well 5 is formed by utilizing the electroforming method, firstly, as shown in FIG. 3A, a metallic film becoming a seed layer 12 is formed in predetermined positions of a semiconductor wafer in which a plurality of CMOSs 21 are formed, and the insulating layer 3 is formed on a surface on a plurality of CMOSs 21 by utilizing a thin film depositing method such as a sputtering method or a vacuum evaporation method. It is enough for the seed layer 12 to have a thickness of several tens of nanometers. For example, the seed layer 12 can be made of Au, Ag, Cu, Ni, Cr, Pt, Pd or an alloy thereof, or a lamination film thereof.

Next, as shown in FIG. 3B, a resist liquid solution is applied to the surface of the semiconductor wafer after completion of the formation of the seed layer 12 by utilizing a spin coat method or the like, or a film resist is stuck thereto, thereby forming a thick resist layer 13. After that, as shown in FIG. 3C, the exposure and the development are carried out, thereby removing the thick resist layer 13 with portions of the thick resist layer 13 becoming the wells 5, respectively, being left.

Also, as shown in FIG. 3D, a metallic film is grown from the seed layer 12 by utilizing the electroforming method (metal plating method), thereby forming the well structure 4. At that time, for example, Au, Ag, Cu, Ni, Cr, Pt, Pd or an alloy thereof, or an alloy of Au, Ag, Cu, Ni, Cr, Pt, or Pd, and Zn, Cd or Pd having corrosion resistance can be used as the material of the wall structure 4. In addition, although a height of the wall structure 4 can be suitably set so as to correspond to the specimen 6 accumulated within the well 5, preferably, it is set as being equal to or larger than 1 μm.

Next, as shown in FIG. 3E, the thick resist layer 13 is removed by using either a peeling solution or dry ashing such as O₂, thereby forming the well 5. Also, when, for example, the specimen 6 is feared to react with the metallic material, as shown in FIG. 3F, the wall structure 4 and the well 5 may be covered with a protective film 7 so as to correspond to the characteristics of the specimen 6. The protective film includes an inorganic material, such as a silicon oxide (SiO₂) or a silicon nitride (SiNₓ), having high permeability, or a polymer material, such as polyimide, having a high melting point and high permeability. It is noted that the protective film 7 has to be formed only when necessary. In addition, when the wall structure 4 is formed by utilizing a nonelectrolytic plating method, the seed layer 12 is also unnecessary.

As has been described, with the method of manufacturing the image sensor according to the second embodiment, the wall structure 4 made of the metallic material is formed by utilizing the electroforming method. Therefore, the multiple reflection is easy to cause within the well 5, and thus the image sensor which is excellent in the light condensing efficiency and the light receiving efficiency can be manufactured at the low cost. In addition, when the electroforming method is utilized, since the removal of the thick resist layer 13 after completion of the formation of the wall structure 4 is easily carried out, it is not feared that the light transmittance is reduced in a bottom portion (light receiving portion) of the well 5 due to the residual material. In addition, since in the image sensor 1, the photoelectric conversion portion and the well are formed integrally with each other, the alignment section becomes unnecessary, and thus manufacturing equipment for the image sensor 1 can be miniaturized and simplified.

### 3. Change of Second Embodiment

### Outline of Method of Manufacturing Image Sensor

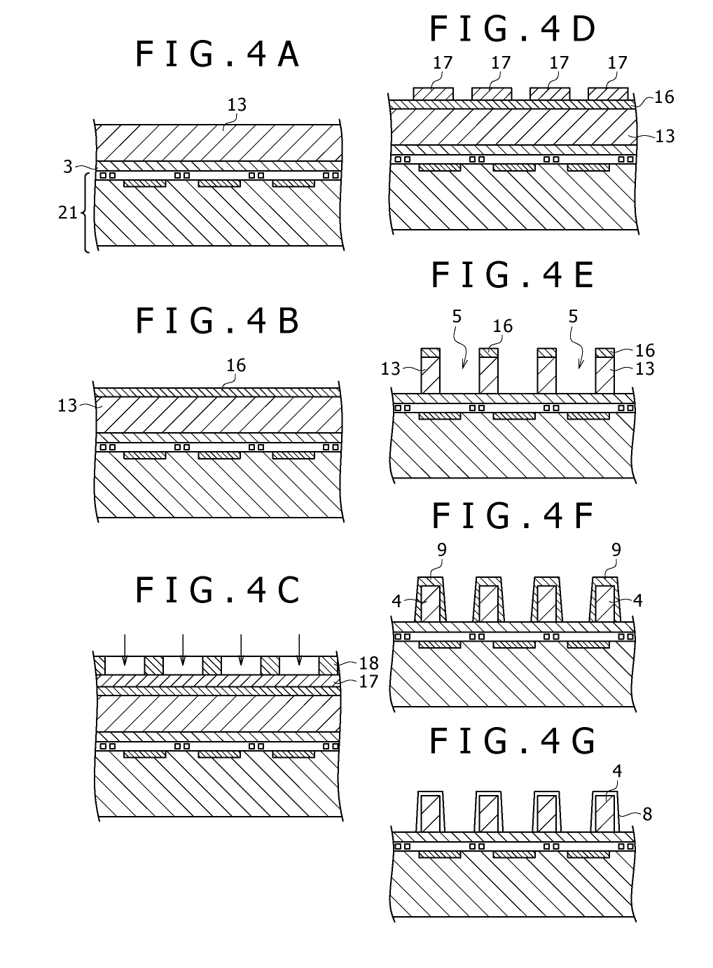

Next, a method of forming the well 5 by using the wall structure including a hard mask layer will be described as a change of the second embodiment with reference to FIGS. 4A to 4G. Although with the method of manufacturing the image sensor 1 according to the second embodiment described above, the wall structure 4 made of the metallic material is formed by utilizing the electroforming method, the present application is by no means limited thereto. That is to say, the wall structure 4 can also be formed by combining a hard mask layer made of a metallic material and a resist layer with each other.

Method of Forming Well

FIGS. 4A to 4G are respectively cross sectional views showing a method of forming the well 5 by using the wall structure including a hard mask layer in the order of processes. In the change of the second embodiment, firstly, as shown in FIG. 4A, the resist liquid solution is applied to the surface of the semiconductor wafer in which a plurality of CMOSs 21 are formed, and the insulating layer 3 is formed on the surface on a plurality of CMOSs 21 by utilizing the spin coat method or the like, or the film resist is stuck thereto, thereby forming the thick resist layer 13. Preferably, a material, such as a polyimide resin or PEEK, having the heat resistance of 200° C. or more is used as the resist material used at that time.

Next, as shown in FIG. 4B, a hard mask 16 made of a metallic material or the like is formed on the thick resist layer 13. After that, as shown in FIG. 4C, a resist layer 17 is formed on the hard mask layer 16, and patterning for formation of the well 5 is carried out by using a mask 18. Also, as shown in FIG. 4D, the exposure and the development are carried out, thereby removing a portion of the resist layer 17 becoming the wall structure 4. In addition, as shown in FIG. 4E, the metal etching, and the etching and ashing of the thick resist layer 13 are carried out, thereby forming the well 5.

When a part of the well structure 4 is composed of the resist layer 13 in such a manner, the light emitted from the specimen is made incident to a side surface of the well 5 (the wall structure 4) to be accidentally detected in the well 5 adjacent to that well by a detecting portion in some cases. For the purpose of preventing such mal-detection to enhance the detection precision, either a reflective layer for reflecting the detection light or an absorptive layer for absorbing the detection light has to be provided on the side surface of the well 5 (the wall structure 4).

When the reflective layer 9 is provided on the wall structure 4, for example, as shown in FIG. 4F, the reflective layer 9 includes a metallic layer made of Au, Ag, Pt, Al or the like has to be formed on the surface of the wall structure 4. In addition, when the absorptive layer is provided on the wall structure 4, for example, as shown in FIG. 4G, after a black resin liquid solution obtained by mixing a resist liquid solution with carbon or the like has to be applied to the surface of the wall structure 4, and the exposure has to be then carried out, post exposure bake and development have to be carried out, thereby forming a black resist layer 8 as an example of the absorptive layer.

With the method of manufacturing the image sensor according to the second embodiment, since the hard mask layer is provided in a part of the wall structure 4, the removal of the thick resist layer 13 after completion of the formation of the wall structure 4 is easily carried out, and thus the image sensor which is excellent in the detection sensitivity and the detection precision can be manufactured at the low cost. It is noted that the constitutions and effects other than those described above in the method of manufacturing the image sensor of the change of the second embodiment are the same as those in the second embodiment described above.

### 4. Third Embodiment

### Structure of Sensor Device

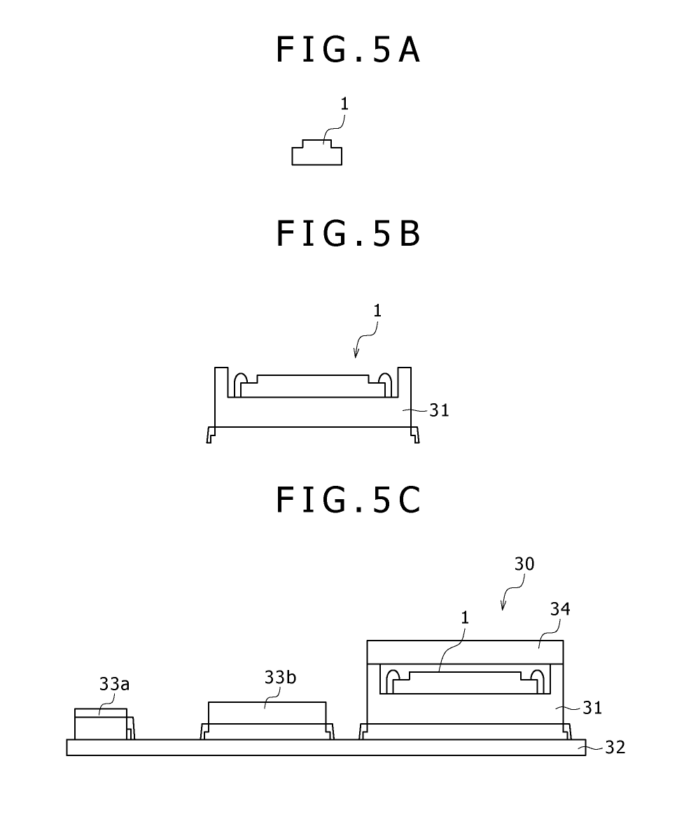

Next, a sensor device according to a third embodiment will be described with reference to FIGS. 5A to 5C. FIGS. 5A to 5C are respectively cross sectional views showing a method of forming a sensor device according to a third embodiment in the order of processes. As shown in FIG. 5C, the sensor device 30 of the third embodiment is such that a package substrate 31 to which the image sensor 1 of the first embodiment described above is mounted is mounted together with other electronic parts or components 33a and 33b onto a circuit board 32.

In the sensor device 30, after the specimen 6 has been filled in the well 5 provided within the image sensor 1, a cap 34 can be placed on the package substrate 31, and the inside of the package can also be encapsulated with an adhesive agent, a light curing agent, thermal compression bond or the like. In this case, a material of the cap 34 is especially by no means limited, and thus can be suitable selected and used.

Method of Manufacturing Sensor Device 30

Next, a method of manufacturing the sensor device 30 described above will be described with reference to FIGS. 5A to 5C. For manufacturing the sensor device 30 of the third embodiment, firstly, the image sensor 1 shown in FIG. 5A is mounted to the package substrate 31 (refer to FIG. 5B). Next, as shown in FIG. 5C, the package substrate 31 to which the image sensor 1 is mounted is mounted together with the electronic parts or components 33a and 33b such as a processing card (FPGA: Field Programmable Gate Array) for processing detected data from the image sensor 1 in real time to the circuit board 32 including a peripheral circuit such as a drive circuit.

Operation

With the sensor device 30 of the third embodiment, when the specimen 6 has been filled in the well 5 provided within the image sensor 1, the optical phenomenon caused in the specimen 6 is detected by the photoelectric conversion portion 2, and is then outputted in the form of a two-dimensional image. At that time, in the case or the like where the sensor device 30 of the third embodiment, for example, is used as the chemical sensor, a light may be radiated from a light source installed in the outside to the specimen 6 filled in the well 5. In addition, in the case where the sensor device 30 of the third embodiment, for example, is used for inspecting a gene, light emission from the specimen 6 itself can also be detected.

Since the image sensor 1 in which the photoelectric conversion portion 2 and the well 5 are formed integrally with each other is mounted to the sensor device 30 of the third embodiment, the alignment section is unnecessary. As a result, the manufacturing equipment for the sensor device 30 can be miniaturized and simplified, and the analysis having the high resolution can be realized at the low cost. In addition, when the image sensor 1 is used in which the wall structure 4 is made of the metallic material, due to the multiple reflection effect within the well 5, the detection efficiency can be largely enhanced as compared with the case of the existing sensor device.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

1. An image sensor comprising:
a photoelectric conversion portion including a light receiving element; and
a well region defined by a wall structure that is formed integrally on the photoelectric conversion portion, wherein the well region is positioned to correspond to the light receiving element of the photoelectric conversion portion.

2. The image sensor of claim 1, wherein the well region is configured as any one of a quadrangular shape and a hexagonal shape.

3. The image sensor of claim 1, wherein the wall structure includes a material selected from the group consisting of Au, Ag, Cu, Ni, Cr, Pt, Pd, Zn, Cd, and an alloy thereof.

4. The image sensor of claim 1, wherein a side surface of the well region includes a side surface material that does not transmit light.

5. The image sensor of claim 1, wherein the well region is configured to receive a biological specimen.

6. The image sensor of claim 5, wherein the light receiving element is configured to detect the light from the biological specimen.

7. The image sensor of claim 5, wherein the well region is covered with a protective film configured to protect the well region from reaction with the biological specimen.

8. The image sensor of claim 1, wherein the photoelectric conversion portion is a charge coupled device or a complementary metal oxide semiconductor.

9. The image sensor of claim 1, further comprising an insulating layer formed between the photoelectric conversion portion and the well region.

10. The image sensor of claim 1, further comprising a light reflective layer formed on the wall structure.

11. The image sensor of claim 1, further comprising a light absorptive layer formed on the wall structure.

12. The image sensor of claim 1, wherein the well region and the light receiving element are substantially same in size.

13. The image sensor of claim 1, wherein the well region is configured to be positioned over the light receiving element.

14. An image sensor device comprising an image sensor including a photoelectric conversion portion and a well region, wherein the photoelectric conversion portion includes a light receiving element, wherein the well region is defined by a wall structure that is formed integrally on the photoelectric conversion portion, and wherein the well region is positioned to correspond to the light receiving element of the photoelectric conversion portion.

15. The image sensor device of claim 14, wherein the well region is configured as any one of a quadrangular shape and a hexagonal shape.

16. The image sensor device of claim 14, wherein the wall structure includes a metal material selected from the group consisting of Au, Ag, Cu, Ni, Cr, Pt, Pd, Zn, Cd, and an alloy thereof.

17. The image sensor device of claim 14, wherein a side surface of the well region includes a side surface material that does not transmit light.

18. The image sensor device of claim 14, wherein the well region is configured to receive a biological specimen.

19. The image sensor device of claim 18, wherein the light receiving element is configured to detect the light from the biological specimen.

20. The image sensor device of claim 18, wherein the well region is covered with a protective film configured to protect the well region from reaction with the biological specimen.

21. The image sensor device of claim 14, wherein the photoelectric conversion portion is a charge coupled device or a complementary metal oxide semiconductor.

22. The image sensor device of claim 14, further comprising an insulating layer formed between the photoelectric conversion portion and the well region.

23. The image sensor device of claim 14, further comprising a light reflective layer formed on the wall structure.

24. The image sensor device of claim 14, further comprising a light absorptive layer formed on the wall structure.

25. The image sensor device of claim 14, wherein the well region and the light receiving element are substantially same in size.

26. The image sensor device of claim 14, wherein the well region is configured to be positioned over the light receiving element.

27. A method of manufacturing an image sensor, comprising:
forming a photoelectric conversion portion including a light receiving element; and
forming a well region defined by a wall structure that is formed integrally on the photoelectric conversion portion, wherein the well region is positioned to correspond to the light receiving element of the photoelectric conversion portion.

28. The method of claim 27, wherein the well region is configured as any one of a quadrangular shape and a hexagonal shape.

29. The method of claim 27, wherein the wall structure includes a metal material selected from the group consisting of Au, Ag, Cu, Ni, Cr, Pt, Pd, Zn, Cd, and an alloy thereof.

30. The method of claim 29, wherein the metal material of the wall structure is formed by electroforming.

31. The method of claim 29, wherein the wall structure is formed by combining a hard mask layer composed of the metal material and a resist layer.

32. The method of claim 27, wherein the well region is configured to receive a biological specimen.

33. The method of claim 32, wherein the light receiving element is configured to detect the light from the biological specimen.

34. The method of claim 32, wherein the well region is covered with a protective film configured to protect the well region from reaction with the biological specimen.

35. The method of claim 27, wherein the photoelectric conversion portion is a charge coupled device or a complementary metal oxide semiconductor.

36. The method of claim 27, further comprising an insulating layer formed between the photoelectric conversion portion and the well region.

37. The method of claim 27, further comprising a light reflective layer formed on the wall structure.

38. The method of claim 27, further comprising a light absorptive layer formed on the wall structure.

39. The method of claim 27, wherein the well region and the light receiving element are substantially same in size.

40. The method of claim 27, wherein the well region is configured to be positioned over the light receiving element.

41. A method of manufacturing an image sensor device including an image sensor, comprising:
forming a photoelectric conversion portion of the image sensor, the photoelectric conversion portion including a light receiving element; and
forming a well region of the image sensor, the well region being defined by a wall structure that is formed integrally on the photoelectric conversion portion, wherein the well region is positioned to correspond to the light receiving element of the photoelectric conversion portion.

42. The method of claim 41, wherein the well region is configured as any one of a quadrangular shape and a hexagonal shape.

43. The method of claim 41, wherein the wall structure includes a metal material selected from the group consisting of Au, Ag, Cu, Ni, Cr, Pt, Pd, Zn, Cd, and an alloy thereof.

44. The method of claim 43, wherein the metal material of the wall structure is formed by electroforming.

45. The method of claim 43, wherein the wall structure is formed by combining a hard mask layer composed of the metal material and a resist layer.

46. The method of claim 41, wherein the well region is configured to receive a biological specimen.

47. The method of claim 46, wherein the light receiving element is configured to detect the light from the biological specimen.

48. The method of claim 46, wherein the well region is covered with a protective film configured to protect the well region from reaction with the biological specimen.

49. The method of claim 41, wherein the photoelectric conversion portion is a charge coupled device or a complementary metal oxide semiconductor.

50. The method of claim 41, further comprising an insulating layer formed between the photoelectric conversion portion and the well region.

51. The method of claim 41, further comprising a light reflective layer formed on the wall structure.

52. The method of claim 41, further comprising a light absorptive layer formed on the wall structure.

53. The method of claim 41, wherein the well region and the light receiving element are substantially same in size.

54. The method of claim 41, wherein the well region is configured to be positioned over the light receiving element.
